(19) United States
(12) Patent Application Publication
(10) Pub. No.: US 2020/0109470 A1
(43) Pub. Date: Apr. 9, 2020

(54) VACUUM EVACUATION SYSTEM

(71) Applicant: EBARA CORPORATION, Tokyo (JP)

(72) Inventors: Masanobu SAITO, Tokyo (JP); Hideo ARAI, Tokyo (JP); Koichi IWASAKI, Tokyo (JP); Toru OSUGA, Tokyo (JP); Atsushi SHIOKAWA, Tokyo (JP)

(21) Appl. No.: 16/585,363

(22) Filed: Sep. 27, 2019

(30) Foreign Application Priority Data
Oct. 3, 2018 (JP) 2018-188257

(51) Int. Cl. C23C 16/44; C23C 14/54; C23C 16/455; F04B 41/06

(52) U.S. Cl. CPC C23C 16/4412; F04B 41/06; C23C 16/45561; C23C 14/54

(57) ABSTRACT

A vacuum evacuation system which can prevent an increase in pressure in one process chamber when evacuating an atmospheric-pressure gas from another process chamber is disclosed. The vacuum evacuation system can be used for evacuating a gas from a plurality of process chambers. The vacuum evacuation system includes: first vacuum pumps; buffer tanks coupled to the first vacuum pumps, respectively; a second vacuum pump; and a collecting pipe providing a communication between the first vacuum pumps and the second vacuum pump.

### CROSS REFERENCE TO RELATED APPLICATION

This document claims priority to Japanese Patent Application Number 2018-188257 filed Oct. 3, 2018, the entire contents of which are hereby incorporated by reference.

### BACKGROUND

A typical semiconductor-device manufacturing apparatus includes a plurality of process chambers each for processing a wafer. In these process chambers, a process, such as a chemical vapor deposition (CVD) process, a dry etching process, or the like, is performed on a plurality of wafers. A processing gas, such as a raw material gas, an etching gas or the like, is used for processing the wafers, and the processing gas is evacuated from the process chambers by a vacuum evacuation system.

FIG. 9 is a schematic diagram of a conventional vacuum evacuation system. As shown in FIG. 9, a semiconductor-device manufacturing apparatus 100 includes a plurality of process chambers 101 and a plurality of turbo molecular pumps 102. The plurality of process chambers 101 are coupled to the turbo molecular pumps 102, respectively. A vacuum evacuation system 110 is coupled to the semiconductor-device manufacturing apparatus 100.

The vacuum evacuation system 110 includes a plurality of booster pumps 111 coupled to the turbo molecular pump 102, respectively, a collecting pipe 113 coupled to the booster pumps 111, and a main pump 112 coupled to the collecting pipe 113. The booster pumps 111 are coupled to inlets of the collecting pipe 113, and the main pump 112 is coupled to an outlet of the collecting pipe 113. The semiconductor-device manufacturing apparatus 100 may not include the turbo molecular pumps 102. In this case, the booster pumps 111 are directly coupled to the plurality of process chambers 101.

The process chambers 101, in which a processing gas is used, require regular or irregular maintenance. When the maintenance is to be performed on one process chamber 101, a valve 103, disposed downstream of that process chamber 101, is closed, and the process chamber 101 is separated from the semiconductor-device manufacturing apparatus 100. Then, the maintenance of the process chamber 101 is performed. Processing of wafers is continued in the other process chambers 101, and the booster pumps 111 and the main pump 112 evacuate the processing gas from the other process chambers 101.

After the maintenance is completed, the process chamber 101 is coupled to the semiconductor-device manufacturing apparatus 100, and the valve 103 is opened. A gas (typically a clean air) having the atmospheric pressure existing in the process chamber 101 that has been subjected to the maintenance is pumped out and pressurized by the booster pump 111 disposed downstream of that process chamber 101, and then flows into the collecting pipe 113. As a result, the pressure in the collecting pipe 113 increases.

The booster pump 111 is a machine that creates a differential pressure between a suction side and a discharge side thereof. Therefore, when the pressure in the collecting pipe 113, i.e., the pressure at the discharge side of the booster pump 111, increases, the pressure at the suction side of the booster pump 111 that is evacuating the processing gas from the process chamber 101 also increases. As a result, the pressure in the process chamber 101 in which processing of a wafer is being performed increases, thus causing the semiconductor-device manufacturing apparatus 100 to detect a pressure abnormality and to stop its operation.

### SUMMARY OF THE INVENTION

According to an embodiment, there is provided a vacuum evacuation system which can prevent an increase in pressure in one process chamber when evacuating an atmospheric-pressure gas from another process chamber.

Embodiments, which will be described below, relate to a vacuum evacuation system used to evacuate a processing gas from a plurality of process chambers for use in, for example, a semiconductor-device manufacturing apparatus.

According to the above-described embodiments, the pressure rise in the vacuum evacuation system (for example, the pressure rise in the collecting pipe), which can occur when the atmospheric pressure gas (for example, clean air) is evacuated from one of the process chambers, is suppressed by a vacuum formed in at least one of the buffer tanks. As a result, the pressure rise in other process chambers can be prevented. Further, the buffer tanks, coupled respectively to the first vacuum pumps, can prevent the increase in pressure in the process chambers when one of the first vacuum pumps is coupled to the vacuum evacuation system after the maintenance is conducted on that first vacuum pump.

### BRIEF DESCRIPTION OF THE DRAWINGS

FIG. 1 is a schematic diagram illustrating an embodiment of a vacuum evacuation system;

FIG. 2 is a schematic diagram showing an embodiment of a pump unit shown in

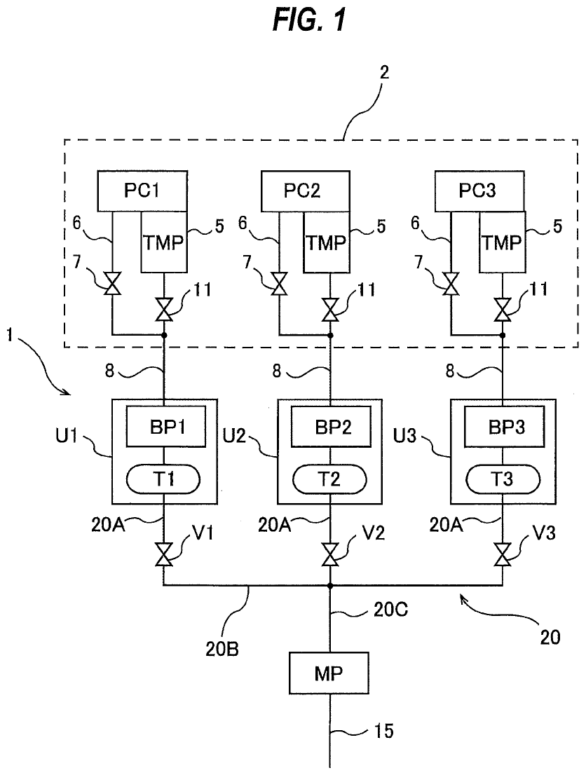

FIG. 1;

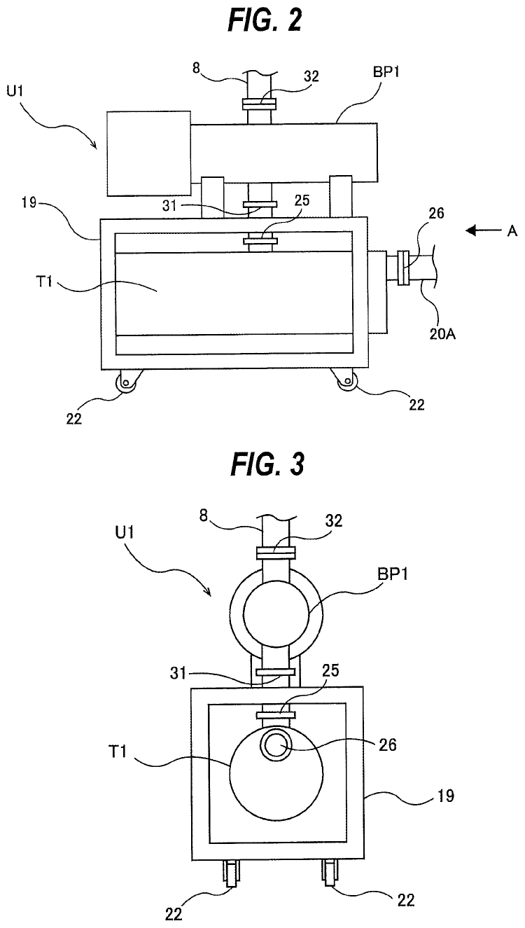

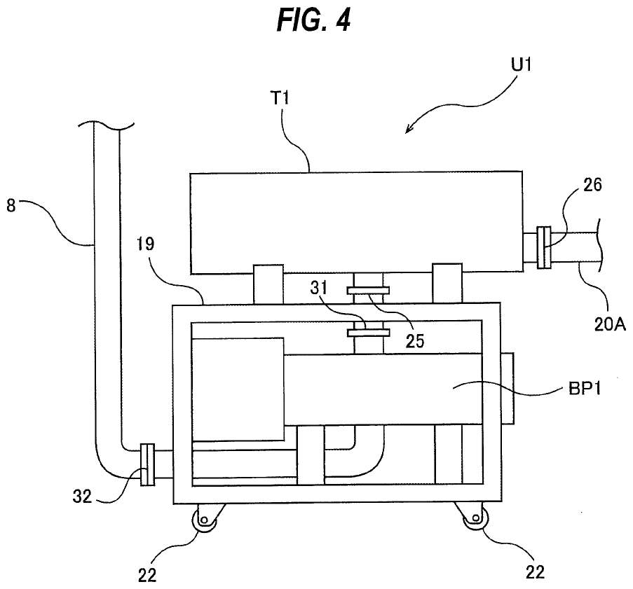

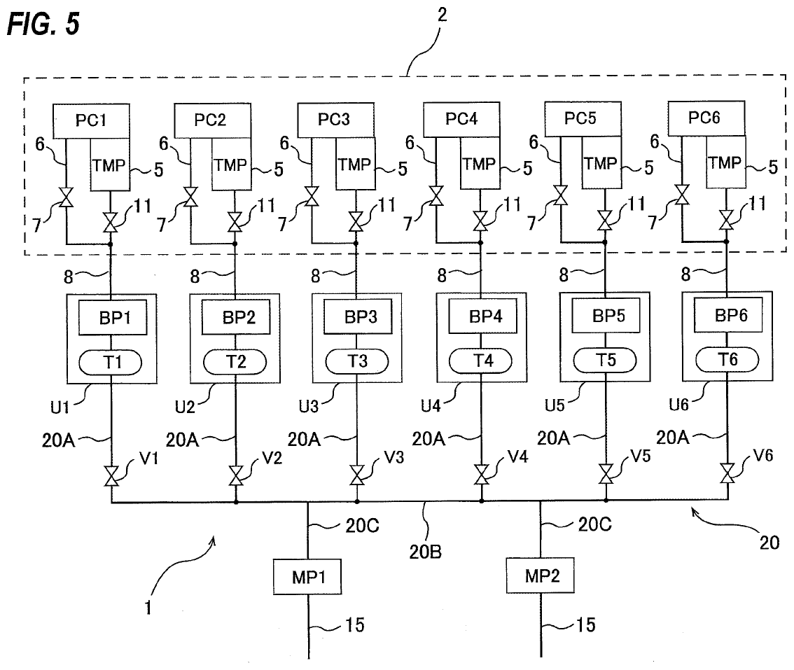

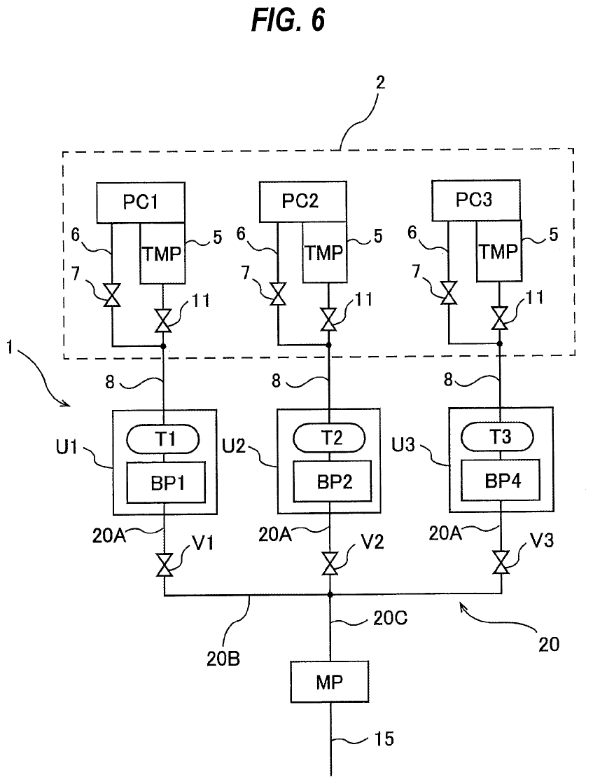

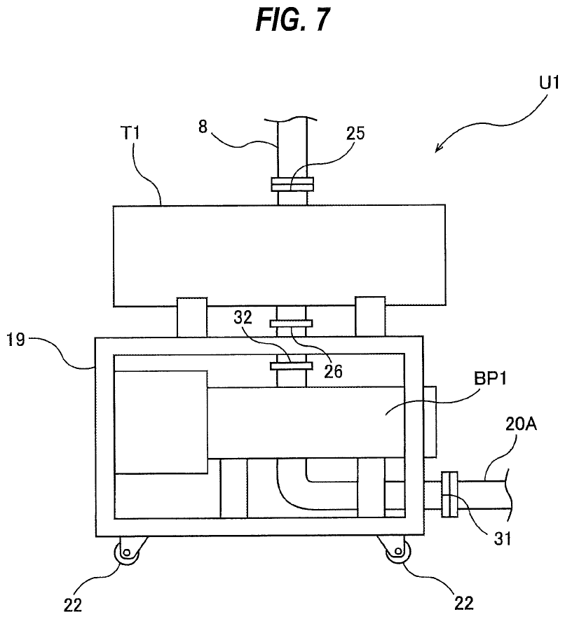

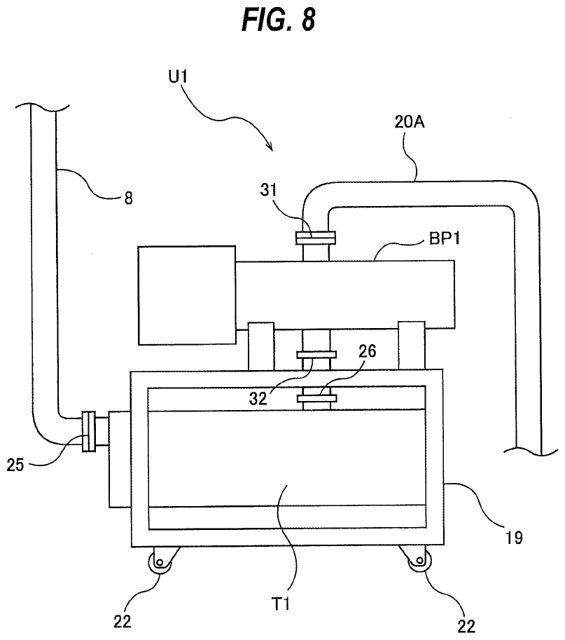

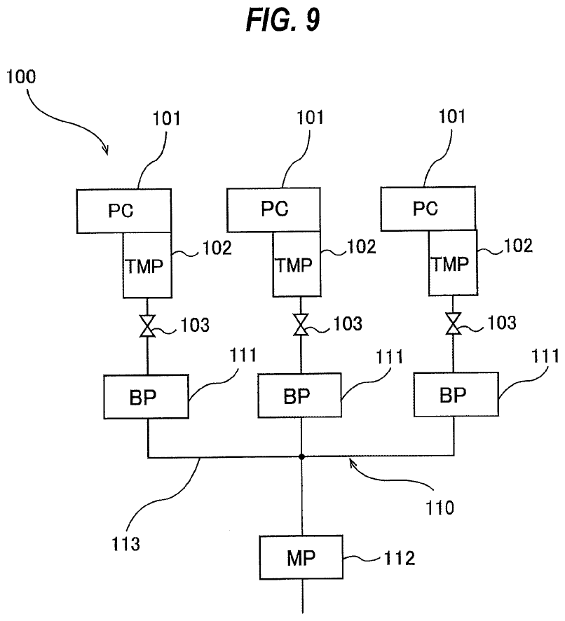

FIG. 3 is a view of the pump unit shown in FIG. 2 as seen from a direction indicated by arrow A;

FIG. 4 is a schematic view showing another embodiment of the pump unit;

FIG. 5 is a schematic view showing another embodiment of the vacuum evacuation system;

FIG. 6 is a schematic view showing still another embodiment of the vacuum evacuation system;

FIG. 7 is a schematic diagram showing an embodiment of the pump unit shown in FIG. 6;

FIG. 8 is a schematic diagram showing another embodiment of the pump unit shown in FIG. 6; and

FIG. 9 is a schematic diagram showing an example of a conventional vacuum evacuation system.

### DESCRIPTION OF EMBODIMENTS

Hereinafter, embodiments will be described with reference to the drawings.

FIG. 1 is a schematic diagram illustrating an embodiment of a vacuum evacuation system. A vacuum evacuation system 1 of the present embodiment is used for evacuating a processing gas from a plurality of process chambers PC1, PC2, PC3 of a semiconductor-device manufacturing apparatus 2. The vacuum evacuation system 1 is coupled to the semiconductor-device manufacturing apparatus 2 by a plurality of connecting pipes 8. In the process chambers PC1 to PC3, processes, such as chemical vapor deposition (CVD) or dry etching, are performed on a plurality of wafers. A processing gas, such as a raw material gas or an etching gas, is used for processing the wafers. The processing gas is evacuated from the process chambers PC1 to PC3 by the vacuum evacuation system 1.

Turbo molecular pumps 5 are coupled to discharge sides of the process chambers PC1 to PC3, respectively. A plurality of bypass pipes 6 are coupled to the plurality of process chambers PC1 to PC3, respectively. The bypass pipes 6 extend so as to bypass the turbo molecular pumps 5. Specifically, one ends of the bypass pipes 6 are coupled to the process chambers PC1 to PC3, respectively, and the other ends of the bypass pipes 6 are coupled to the connecting pipes 8, respectively. A plurality of bypass valves 7 are attached to the plurality of bypass pipes 6, respectively. These bypass valves 7 are closed while the processing gas is evacuated from the process chambers PC1 to PC3.

The vacuum evacuation system 1 includes a plurality of first vacuum pumps BP1, BP2, BP3, a plurality of buffer tanks T1, T2, T3 coupled to the first vacuum pumps BP1, BP2, BP3, respectively, a second vacuum pump MP, and a collecting pipe 20 through with the plurality of first vacuum pumps BP1, BP2, BP3 communicate with the second vacuum pump MP. The number of first vacuum pumps BP1 to BP3 is the same as the number of process chambers PC1 to PC3. Accordingly, the first vacuum pumps BP1 to BP3 are coupled to the plurality of process chambers PC1 to PC3 of the semiconductor-device manufacturing apparatus 2, respectively.

In the present embodiment, the first vacuum pumps BP1 to BP3 are coupled to the process chambers PC1 to PC3, respectively, through the connecting pipes 8 and the turbo molecular pumps 5. The semiconductor-device manufacturing apparatus 2 may not include the turbo molecular pumps 5, the bypass pipes 6, and the bypass valves 7. In such a configuration, the first vacuum pumps BP1 to BP3 are coupled to the plurality of process chambers PC1 to PC3 through the connecting pipes 8. Connecting valves 11 are attached to the connecting pipes 8, respectively. When the processing gas is evacuated from the process chambers PC1 to PC3, these connecting valves 11 are open.

The second vacuum pump MP is arranged downstream of the first vacuum pumps BP1 to BP3 and the buffer tanks T1 to T3. The first vacuum pumps BP1 to BP3 are mechanical booster pumps. In the present embodiment, single-stage positive displacement vacuum pumps are used as the first vacuum pumps BP1 to BP3. Specific examples of the single-stage positive displacement vacuum pump include a Roots-type vacuum pump, a claw-type vacuum pump, and a screw-type vacuum pump. In one embodiment, the first vacuum pumps BP1 to BP3 may be multistage positive displacement vacuum pumps. The second vacuum pump MP is a multistage positive displacement vacuum pump. Specific examples of the multistage positive displacement vacuum pump include a Roots-type vacuum pump, a claw-type vacuum pump, a screw-type vacuum pump, and a combined pump that includes a combination of the aforementioned types.

The plurality of buffer tanks T1 to T3 are coupled to the discharge sides of the plurality of first vacuum pumps BP1 to BP3, respectively. The buffer tank T1 to T3 are hollow tanks. The first vacuum pumps BP1 to BP3 and the corresponding buffer tanks T1 to T3 are unitized, and constitute a plurality of pump units U1, U2, U3. Specifically, the pump unit U1 includes at least the first vacuum pump BP1 and the corresponding buffer tank T1, the pump unit U2 includes at least the first vacuum pump BP2 and the corresponding buffer tank T2, and the pump unit U3 includes at least the first vacuum pump BP3 and the corresponding buffer tank T3.

The collecting pipe 20 includes a plurality of inlet pipes 20A, one horizontal pipe 20B to which these inlet pipes 20A are coupled, and one outlet pipe 20C coupled to the horizontal pipe 20B. The plurality of inlet pipes 20A are coupled to the buffer tanks T1 to T3, respectively. The outlet pipe 20C is coupled to a suction port of the second vacuum pump MP. A discharge port of the second vacuum pump MP is coupled to a delivery pipe 15. A plurality of shut-off valves V1, V2, V3 are attached to the plurality of inlet pipes 20A, respectively. During normal operation of the vacuum evacuation system 1, the shut-off valves V1, V2, and V3 are open.

The vacuum evacuation system 1 is operated as follows. The bypass valves 7 are opened and the connecting valves 11 are closed. Next, the second vacuum pump MP is started to operate, and then the plurality of first vacuum pumps BP1 to BP3 are started to operate. A gas having the atmospheric pressure (typically a clean air) in the process chambers PC1 to PC3 flows through the bypass pipes 6, and is evacuated by the first vacuum pumps BP1 to BP3 and the second vacuum pump MP of the vacuum evacuation system 1. When the pressures in the process chambers PC1 to PC3 decrease to a predetermined first pressure, the bypass valves 7 are closed, the connecting valves 11 are opened, and the turbo molecular pumps 5 are started to operate. When the pressures in the process chambers PC1 to PC3 decrease to a predetermined second pressure, the processing gas is introduced into the process chambers PC1 to PC3. The processing gas is evacuated from the process chambers PC1 to PC3 by the turbo molecular pumps 5, the first vacuum pumps BP1 to BP3, and the second vacuum pump MP. As described above, the turbo molecular pumps 5 may not be provided. In such a case, the processing gas is evacuated from the process chambers PC1 to PC3 by the first vacuum pumps BP1 to BP3 and the second vacuum pump MP.

The process chambers PC1 to PC3 require regular or irregular maintenance. For example, when maintenance of the process chamber PC1 is to be conducted, the connecting valve 11 located downstream of the process chamber PC1 is closed, and the operations of the turbo molecular pump 5 and the first vacuum pump BP1 coupled to the process chamber PC1 are stopped. The process chamber PC1 is removed from the semiconductor-device manufacturing apparatus 2, and the maintenance of the process chamber PC1 is conducted. The other first vacuum pumps BP2 and BP3 and the second vacuum pump MP continue to operate, so that processing of wafers is continued in the other process chambers PC2 and PC3.

After the maintenance is completed, the process chamber PC1 is coupled to the semiconductor-device manufacturing apparatus 2. A gas having the atmospheric pressure (typically a clean air) exists in the process chamber PC1 that has been subjected to the maintenance. Therefore, first, the atmospheric-pressure gas is evacuated from the process chamber PC1. Specifically, the first vacuum pump BP1 is started to operate, and the bypass valve 7 coupled to the process chamber PC1 is opened. The atmospheric-pressure gas (e.g., clean air) is evacuated from the process chamber PC1 by the first vacuum pump BP1, and flows through the buffer tank T1 into the collecting pipe 20. At this time, since the vacuum is already produced in the other buffer tanks T2 and T3 coupled to the collecting pipe 20, the pressure rise in the collecting pipe 20 is suppressed. Since the second vacuum pump MP is in operation, the pressure in the collecting pipe 20 quickly decreases to the original pressure.

According to this embodiment, the pressure rise in the collecting pipe 20 is suppressed by the vacuum in the other buffer tanks T2 and T3. Therefore, when the gas having the atmospheric pressure is evacuated from the process chamber PC1, the pressure rise in the other process chambers PC2 and PC3 is prevented. The semiconductor-device manufacturing apparatus 2 can continue processing of wafers, such as chemical vapor deposition (CVD) or dry etching, in the other process chambers PC2 and PC3. Operation of the process chamber PC2 or the process chamber PC3 and operation after completion of the maintenance are the same as the above-described operations, and therefore repetitive descriptions are omitted.

The plurality of buffer tanks T1, T2, T3 are provided corresponding to the plurality of first vacuum pumps BP1, BP2, BP3. Specifically, the number of buffer tanks T1 to T3 is equal to the number of first vacuum pumps BP1 to BP3. Further, the buffer tanks T1 to T3 are distributed throughout the entirety of the collecting pipe 20. According to such an arrangement, when the atmospheric gas is evacuated from any one of the plurality of process chambers PC1 to PC3, the pressure rise in the collecting pipe 20 can be quickly relieved regardless of the position of that process chamber.

As described above, the vacuum evacuation system 1 includes the plurality of pump units U1 to U3 including the plurality of first vacuum pumps BP1 to BP3 and the plurality of buffer tanks T1 to T3. These pump units U1 to U3 have the same configuration. Therefore, the pump unit U1 including the first vacuum pump BP1 and the buffer tank T1 will be described below with reference to FIGS. 2 and 3.

FIG. 2 is a schematic view showing an embodiment of the pump unit U1 including the first vacuum pump BP1 and the buffer tank T1, and FIG. 3 is a view of the pump unit U1 shown in FIG. 2 as seen from a direction indicated by arrow A. The pump unit U1 includes the single first vacuum pump BP1, the single buffer tank T1, and a common base 19. In this embodiment, the base 19 is comprised of frames. The first vacuum pump BP1 is fixed to an upper part of the base 19, and the buffer tank T1 is fixed to a lower part of the base 19. Casters 22 are fixed to a bottom of the base 19 so that the entire pump unit U1 can be moved.

The first vacuum pump BP1 is arranged below the buffer tank T1. The buffer tank T1 is located downstream of the first vacuum pump BP1. The buffer tank T1 has a first opening 25 in its upper portion, and further has a second opening 26 in its side portion. The second opening 26 may be formed in a lower portion of the buffer tank T1. The first opening 25 of the buffer tank T1 is coupled to the discharge port 31 of the first vacuum pump BP1, and the second opening 26 of the buffer tank T1 is coupled to the inlet pipe 20A of the collecting pipe 20. The suction port 32 of the first vacuum pump BP1 is coupled to the connecting pipe 8. The first opening 25 of the buffer tank T1 may be directly coupled to the discharge port 31 of the first vacuum pump BP1, or may be coupled to the discharge port 31 of the first vacuum pump BP1 through a pipe, such as a flexible tube or a joint tube.

A capacity of the buffer tank T1 is determined based on factors, such as capacities of the process chamber PC1 and the collecting pipe 20, a target vacuum pressure for the process chamber PC1, and the like. In this embodiment, the capacity of the buffer tank T1 is larger than the capacity of the first vacuum pump BP1, while in one embodiment, the capacities of the buffer tanks T1 to T3 may be smaller than the capacities of the first vacuum pumps BP1 to BP3.

According to the present embodiment, the buffer tank T1 is located below the first vacuum pump BP1. This arrangement does not require an installation area for the buffer tank T1, and can reduce an installation area necessary for the entire vacuum evacuation system 1. If a floor area where the pump unit U1 is installed is sufficiently large, the buffer tank T1 may be arranged beside the first vacuum pump BP1.

In one embodiment, as shown in FIG. 4, the buffer tank T1 may be arranged above the first vacuum pump BP1. The buffer tank T1 is fixed to the upper part of the base 19, and the first vacuum pump BP1 is fixed to the lower part of the base 19. The embodiment shown in FIG. 4 is the same as the embodiment shown in FIGS. 2 and 3 in that the buffer tank T1 is located downstream of (at the discharge side of) the first vacuum pump BP1, but is different in that the buffer tank T1 is arranged above the first vacuum pump BP1. The embodiment shown in FIG. 4 has an advantage that the installation area for the vacuum evacuation system 1 can be reduced as well as the embodiment shown in FIGS. 2 and 3.

In the present embodiment, the processing gas, such as a raw material gas or an etching gas used for processing of wafers, is evacuated from the process chambers PC1 to PC3 by the vacuum evacuation system 1. When the processing gas is evacuated by the vacuum evacuation system 1, by-product is generated from the processing gas. The by-product is solidified and gradually deposited in the first vacuum pumps BP1 to BP3. The solidified by-product may enter the buffer tanks T1 to T3. Thus, the maintenance of the first vacuum pumps BP1 to BP3 and the maintenance of the buffer tanks T1 to T3 are required regularly or irregularly.

In the present embodiment, the plurality of first vacuum pumps BP1 to BP3, the plurality of buffer tanks T1 to T3, and the plurality of bases 19 (see FIGS. 2 to 4) constitute the plurality of pump units U1 to U3. According to such configurations, after the maintenance of any one of the pump units U1 to U3 is conducted, the gas having the atmospheric pressure is evacuated from that pump unit, while operations of the other pump units can be continued without causing the increase in the pressure in the other process chambers.

For example, when the maintenance of the pump unit U1 is to be conducted, first, the shut-off valve V1, arranged downstream of the pump unit U1, is closed. Thereafter, the pump unit U1 is removed from the vacuum evacuation system 1. The other pump units U2 and U3 continue their operations, and processing of wafers is continued in the process chambers PC2 and PC3. The maintenance of the pump unit U1 is conducted, and the pump unit U1 is then coupled to the vacuum evacuation system 1. Further, the shut-off valve V1 is opened. The atmospheric-pressure gas (typically the clean air) in the first vacuum pump BP1 and the buffer tank T1 of the pump unit U1 flows into the collecting pipe 20, and the pressure in the collecting pipe 20 increases. At this time, the vacuum is already produced in the other buffer tanks T2 and T3 coupled to the collecting pipe 20. Therefore, the pressure rise in the collecting pipe 20 is lessened. Since the second vacuum pump MP is in operation, the pressure in the collecting pipe 20 is quickly lowered to the original pressure.

As described above, the configurations of the present embodiment can prevent the increase in the pressure in the process chambers PC2 and PC3 coupled to the other pump units U2 and U3 when the pump unit U1 that has been subjected to maintenance is coupled to the vacuum evacuation system 1. Operation of the maintenance of the pump unit U2 or the pump unit U3, and operation after the termination of maintenance are the same as the above-described operations. Therefore, the repetitive descriptions are omitted.

In the embodiment shown in FIG. 1, the vacuum evacuation system 1 has three first vacuum pumps BP1 to BP3 and one second vacuum pump MP, but the present invention is not limited to this embodiment. The number of first vacuum pumps BP1 to BP3 to be provided corresponds to the number of process chambers PC1 to PC3 of the semiconductor-device manufacturing apparatus 2. A plurality of second vacuum pumps MP may be provided.

For example, as shown in FIG. 5, the vacuum evacuation system 1 may include six first vacuum pumps BP1 to BP6 and six buffer tanks T1 to T6 (i.e., six pump units U1 to U6) corresponding to six process chambers PC1 to PC6, and may further include two second vacuum pumps MP1 and MP2 arranged downstream of the first vacuum pumps BP1 to BP6 and the buffer tanks T1 to T6. The collecting pipe 20 includes six inlet pipes 20A coupled to the first vacuum pumps BP1 to BP6 through buffer tanks T1 to T6, respectively, one horizontal pipe 20B to which the six inlet pipes 20A are coupled, and two outlet pipes 20C coupled to the horizontal pipe 20B. The two second vacuum pumps MP1 and MP2 are coupled to the two outlet pipes 20C, respectively. The number of second vacuum pumps MP1 and MP2 is smaller than the number of first vacuum pumps BP1 to BP6, and the number of outlet pipes 20C is smaller than the number of inlet pipes 20A. The configuration and operation of this embodiment that are not specifically described are the same as those of the embodiment described with reference to FIGS. 1 to 4, and therefore repetitive descriptions are omitted.

FIG. 6 is a schematic view showing still another embodiment of the vacuum evacuation system 1. The configuration and operation of the present embodiment, which will not be specifically described, are the same as those of the embodiment described with reference to FIG. 1, and therefore the repetitive descriptions are omitted. In the present embodiment, the buffer tanks T1 to T3 are arranged upstream of the first vacuum pumps BP1 to BP3, respectively. The connecting pipes 8 are coupled to the buffer tanks T1 to T3, respectively. Therefore, in the present embodiment, the first vacuum pumps BP1 to BP3 are coupled to the process chambers PC1 to PC3, respectively, through the buffer tanks T1 to T3, the connecting pipes 8, and the turbo molecular pumps 5. The turbo molecular pumps 5 may not be provided.

The vacuum evacuation system 1 according to this embodiment can also prevent the increase in pressure in other process chambers while evacuating the atmospheric gas (for example, a clean air) from any one of the plurality of process chambers PC1 to PC3. For example, when the atmospheric-pressure gas is evacuated from the process chamber PC1 by the first vacuum pump BP1, the pressure in the collecting pipe 20 increases. As the pressure increases, the pressure at the suction sides of the other first vacuum pumps BP2 and BP3 increases. Since the vacuum is already produced in the buffer tanks T2 and T3, the increase in the pressure at the suction sides of the first vacuum pumps BP2 and BP3 is lessened by the vacuum in the buffer tanks T2 and T3. As a result, the pressure rise in the process chambers PC2 and PC3 arranged upstream of the buffer tanks T2 and T3 is prevented.

According to this embodiment, the pressure rise in the collecting pipe 20 is lessened by the vacuum in the other buffer tanks T2 and T3. Therefore, when the gas having the atmospheric pressure is evacuated from the process chamber PC1, the increase in pressure in the other process chambers PC2 and PC3 can be prevented. The semiconductor-device manufacturing apparatus 2 can continue processing of wafers, such as chemical vapor deposition (CVD) and dry etching, in the other process chambers PC2 and PC3.

FIG. 7 is a schematic diagram showing an embodiment of the pump unit U1 shown in FIG. 6. The configuration and operation of the present embodiment, which will not be specifically described, are the same as those of the embodiment shown in FIGS. 2 and 3, and therefore repetitive descriptions thereof are omitted. The pump units U2 and U3 have the same configurations as the pump unit U1. As shown in FIG. 7, the buffer tank T1 is fixed to the upper part of the base 19, and the first vacuum pump BP1 is fixed to the lower part of the base 19.

The first vacuum pump BP1 is arranged below the buffer tank T1. The buffer tank T1 is located upstream of the first vacuum pump BP1. The buffer tank T1 has a first opening 25 in an upper portion thereof, and further has a second opening part 26 in a lower portion thereof. The first opening 25 of the buffer tank T1 is coupled to the connecting pipe 8, and the second opening 26 of the buffer tank T1 is coupled to the suction port 32 of the first vacuum pump BP1. The discharge port 31 of the first vacuum pump BP1 is coupled to the inlet pipe 20A of the collecting pipe 20. The second opening 26 of the buffer tank T1 may be directly coupled to the suction port 32 of the first vacuum pump BP1, or may be coupled to the suction port 32 of the first vacuum pump BP1 through a pipe, such as a flexible pipe or a joint pipe.

According to the present embodiment, the buffer tank T1 is arranged above the first vacuum pump BP1. This arrangement does not require a footprint for installing the buffer tank T1, and can reduce the entire installation area of the vacuum evacuation system 1. If the installation area for the pump unit U1 is sufficiently large, the buffer tank T1 may be arranged beside the first vacuum pump BP1.

In one embodiment, as shown in FIG. 8, the buffer tank T1 may be arranged below the first vacuum pump BP1. The buffer tank T1 is fixed to the lower part of the base 19, and the first vacuum pump BP1 is fixed to the upper part of the base 19. The embodiment shown in FIG. 8 is the same as the embodiment shown in FIG. 7 in that the buffer tank T1 is arranged upstream of the first vacuum pump BP1, but is different in that the buffer tank T1 is located below the first vacuum pump BP1. The embodiment shown in FIG. 8 has an advantage that the installation area for the vacuum evacuation system 1 can be reduced as well as the embodiment shown in FIG. 7.

Also in this embodiment, the plurality of first vacuum pumps BP1 to BP3, the plurality of buffer tanks T1 to T3, and the plurality of bases 19 (see FIGS. 7 and 8) constitute the plurality of pump units U1 to U3. According to such configuration, the maintenance of any one of the pump units U1 to U3 is conducted, and then the gas having the atmospheric pressure is evacuated from that pump unit, while operations of the other pump units can be continued without causing the increase in the pressure in the other process chambers.

In the embodiment shown in FIG. 6, the vacuum evacuation system 1 includes three first vacuum pumps BP1 to BP3 and one second vacuum pump MP, but the present invention is not limited to this embodiment. The embodiment shown in FIG. 5 can be applied to the embodiment shown in FIG. 6.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A vacuum evacuation system for evacuating a gas from a plurality of process chambers, comprising:
first vacuum pumps;
buffer tanks coupled to the first vacuum pumps, respectively;
a second vacuum pump; and
a collecting pipe providing a communication between the first vacuum pumps and the second vacuum pump.

2. The vacuum evacuation system according to claim 1, further comprising bases,
wherein the first vacuum pumps are fixed to the bases, respectively,
the buffer tanks are fixed to the bases, respectively, and
the first vacuum pumps, the buffer tanks, and the bases constitute pump units.

3. The vacuum evacuation system according to claim 1, wherein the buffer tanks are arranged downstream of the first vacuum pumps, respectively.

4. The vacuum evacuation system according to claim 3, wherein the buffer tanks are arranged below the first vacuum pumps, respectively.

5. The vacuum evacuation system according to claim 1, wherein the buffer tanks are arranged upstream of the first vacuum pumps, respectively.

6. The vacuum evacuation system according to claim 5, wherein the buffer tanks are arranged above the first vacuum pumps, respectively.
